(19) United States
(12) Patent Application Publication
(10) Pub. No.: US 2006/0191636 A1
(43) Pub. Date: Aug. 31, 2006

(54) Valve assembly, semiconductor device manufacturing apparatus comprising the same, and method of cleaning a trap of a semiconductor device manufactuing apparatus

(76) Inventor: Hae-Moon Choi, Hwaseong-gun (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/338,833

(22) Filed: Jan. 25, 2006

(30) Foreign Application Priority Data
Jan. 25, 2005 (KR) 2005-06836

(51) Int. Cl. H01L 21/306; C23C 16/00

(52) U.S. Cl. 156/345.29; 118/715

(57) ABSTRACT

A valve assembly prevents leaks in an exhaust system of a semiconductor device manufacturing apparatus. One side of a body of the valve assembly is connected to a process chamber or a pump, and the side is connected to a trap. The valve body defines a passageway through which gas flows through the valve body. Three valves mounted to the body are open while gas is being discharged from the process chamber, and are closed when the trap is being cleaned. The valves divide the passageway into a first region located between the first and second valves, and a second region located between the second and third valves. A high pressure is maintained in the first region, and a low pressure is maintained in the second region when the valves are closed and cleaning solution is being supplied into the trap.

### BACKGROUND OF THE INVENTION

1. Field of the Invention

The present invention relates to apparatuses for manufacturing semiconductor devices and the like. More particularly, the present invention relates to a semiconductor manufacturing apparatus having traps installed in a vacuum exhaust line, i.e., in a vent line.

2. Description of the Related Art

In general, a semiconductor device is manufactured by depositing films on a wafer and etching the films. The deposition and etching processes are carried out in process chambers under high pressure using harmful gas such as silane, arsine, TiCl4-NH4, or boron chloride, and processing gas such as hydrogen. As a result, large amounts of explosive gases, erosive impurities, and noxious gases containing fluid components are generated as by-products of the deposition and etching processes. For this reason, typical semiconductor manufacturing apparatuses are provided with scrubbers designed to clean various types of gas. The scrubbers are installed downstream of the vacuum pumps which create the vacuum states in the process chambers and discharge exhaust gas from the process chambers.

However, such exhaust gas readily solidifies into a powder when it is exposed to the atmosphere or when its temperature is lowered upon flowing through relatively cool peripheral components of the apparatus. If the powder adheres to a venting line, the pressure in the vent line could increase to such an extent that the exhaust gas would a flow back into the process chamber. In this case, wafers in the process chamber would be contaminated by the exhaust gas. Thus, a trap is provided between the process chamber and the vacuum pump to collect powder formed from the exhaust gas that has been discharged from the process chamber.

However, the amount of the powder adhering to the inside of a trap increases with the time during which the manufacturing processes are run. Thus, if the manufacturing processes are run for a long period of time, the spaces in the trap through which the exhaust gas passes become rather narrow. Thus, after a predetermined time, the operation of the vacuum pump and the other components associated with carrying out the manufacturing process in the process chamber are shut down. Then the trap is cleaned or replaced with a new trap. Typical semiconductor device manufacturing apparatuses employ two traps, as shown in FIG. 1, to prevent downtime of the apparatus that would otherwise occur when a trap is cleaned or replaced.

More specifically, FIG. 1 schematically illustrates ventilation structure of a typical semiconductor manufacturing apparatus, e.g., a low-pressure chemical vapor deposition (LPCVD) apparatus. As illustrated in FIG. 1, traps 932 and 934 and a pump 920 are disposed in a vent line 20 leading to a vent outlet of a process chamber 910 of the apparatus. The pump 920 maintains a vacuum in the process chamber 910, and the traps 932 and 934 collect impurities, in the form of powder, to prevent the impurities from flowing to the pump 920. Also, a system of de-ionized water supply and exhaust lines (not shown) may be provided for cleaning the traps 932 and 934 without the need to separate them from the vent line.

In any case, the first trap 932 is used exclusively to collect the impurities in the exhaust gas until there is too much powder adhering to the first trap 932. At this time, the first trap 932 is cleaned or replaced, and the second trap 934 is used instead. More specifically, in the case in which the first trap 932 is cleaned, first and second valves V1 and V2 are closed and de-ionized water (DIW) is supplied to the first trap 932. During this time, third and fourth valves V3 and V4 are open to enable the exhaust gas to flow through the second trap 934. Thus, it is possible to continue trapping impurities, i.e., processing residue, without stopping the operation of the process chamber 910 and the pump 920.

However, the de-ionized water may leak into the vacuum line 940 through the first and second valves V1 and V2 when the first trap 932 is cleaned. In this case, the vacuum line 940 leading to the process chamber 910 or the wafer in the process chamber 910 would be contaminated.

### SUMMARY OF THE INVENTION

An object of the invention is to provide a valve assembly capable of preventing de-ionized water or external impurities from flowing into a vent line due to valve leaks when a trap is being cleaned or replaced.

Another object of the present invention is to provide a substrate processing apparatus, such as a semiconductor device manufacturing apparatus, that prevents a backflow from occurring in the venting/exhaust system thereof, and thereby prevents the substrates being processed from being contaminated.

Still another object of the present invention is to provide a method of cleaning a trap(s) of a substrate processing apparatus in such a way as to prevent impurities from leaking to the process chamber or vacuum pump of the apparatus.

According to one aspect of the present invention, there is provided a valve assembly in which the pressure can be adjusted to prevent fluid from flowing therethrough even if the valves thereof are leaking. The valve assembly includes a body, and first and second valves mounted to the body. The body has first and second ports and defines a passageway extending therein between the ports. A first one of the valves is mounted to the body and is openable and closable to selectively open and close the passageway in the body. A second one of the valves is mounted to the body and is openable and closable to selectively open and close the passageway in the body. A first region of the passageway is delimited by and between the first and second valves. The body also has an inlet extending therethrough in direct fluid communication with the first region to accommodate a pressure control unit. The pressure control unit regulates the pressure in the first region when the first and second valves are closed.

The valve assembly may further comprise a third valve mounted to the body and openable and closable to selectively open and close the passageway in the body. A second region of the passageway is delimited by and between the second and third valves. In this case, the body has a second inlet configured to accommodate a second pressure control unit that regulates the pressure in the second region. The second pressure control unit includes a vacuum line connected to the second inlet to exhaust fluid from the second region and thereby maintain a low level of pressure, namely a vacuum, in the second region.

According to another aspect of the invention, there is provided a substrate processing apparatus comprising a process chamber and an exhaust/venting system that is prevented from creating a backflow of potential contaminants. The venting system includes a vacuum pump, a vent line extending between and connecting the process chamber and the vacuum pump, at least one trap disposed in the vent line so as to collect by-products exhausted from the process chamber, and one or more valve assemblies disposed in the vent line in-line with the trap. Each valve assembly is disposed between the process chamber and the trap or between the pump and the trap. Also, each valve assembly comprises a body having first and second ports and defines a passageway extending therein between the ports, first and second valves mounted to the body and which are openable and closable to selectively open and close the passageway within the body, and a pressure control unit. A first region of the passageway is delimited by and between the first and second valves. The pressure control unit is in fluid communication with the first region and is operative to control the pressure in the first region so that fluid can be prevented from leaking past the first and second valves when the first and second valves are closed.

The pressure control unit may include a gas injection supply line open to the first region, and a source of gas to which the line is connected so that gas can be supplied into the first region to produce a high level of pressure in the first region.

The valve assembly may further comprise a third valve and a second pressure control unit. The third valve is mounted to the body and is openable and closable to selectively open and close the passageway in the body. A second region of the passageway is delimited by and between the second and third valves. The second pressure control unit includes a vacuum line connected to the second inlet to exhaust fluid from the second region and thereby maintain a low level of pressure, namely a vacuum, in the second region. The vacuum line may be connected to the vacuum pump.

According to another aspect of the invention, the vent line includes a first section at which the vent line is connected to the process chamber, a second section at which the vent line is connected to the vacuum pump, and first and second branches disposed parallel to one another as extending between and connected to the first and second section. A first trap is disposed in the first branch and a second trap is disposed in the second branch. First ones of the valve assemblies are disposed in the first branch at opposite sides of the first trap, respectively, and second ones of the valve assemblies are disposed in the second branch at opposite sides of second first trap, respectively.

According to still another aspect of the invention, there is provided a method of cleaning a trap, in a substrate processing apparatus having a valve assembly as described above, in such a way that the cleaning process will not contaminate the process chamber and/or the vacuum pump. First, the first and second valves of the valve assembly interposed between the trap and the process chamber and/or of the valve assembly interposed between the trap and the vacuum pump are closed. The pressure in the first region of the passageway of the valve assembly/assemblies is adjusted. Then a cleaning solution is supplied into the trap once the pressure in the first region has reached a level that will prevent fluid from flowing through the valve assembly past the closed valves.

When the valve assembly has a third valve and the passageway in the body of the valve assembly has the second region located between the second and third valves, the pressure is adjusted in the first region by injecting gas into the first region, and the pressure is adjusted in the second region by evacuating the second region. Preferably, the gas is injected such that the pressure in the first region is raised to above the pressure of the cleaning solution in the trap, and is maintained at least until the cleaning solution is no longer being supplied into the trap. On the other hand, the second region is evacuated until the pressure therein is less than the pressure prevailing in the process chamber or vacuum pump depending on which side of the trap the valve assembly is located.

### BRIEF DESCRIPTION OF THE DRAWINGS

These and other objects, features and advantages of the present invention will become more apparent from the following detailed description of the preferred embodiments that follows as made with reference to the accompanying drawings. In the drawings:

FIG. 1 is a schematic diagram of a conventional semiconductor device manufacturing apparatus;

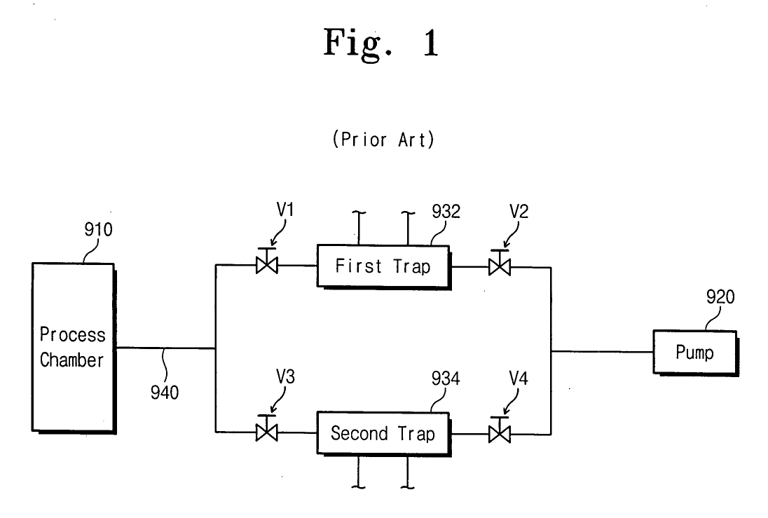

FIG. 2 is a schematic diagram of an embodiment of a semiconductor device manufacturing apparatus in accordance with the invention;

FIG. 3 is a sectional view of a portion of the vent system of the apparatus shown in FIG. 2;

FIG. 4 is a sectional view of a valve assembly of the vent system of the apparatus shown in FIG. 2;

FIG. 5 is a sectional of the valve assembly while a trap of the apparatus shown in FIG. 2 is being cleaned; and

FIGS. 6 and 7 are sectional views of other embodiments of the valve assembly according to the present invention.

### DETAILED DESCRIPTION OF PREFERRED EMBODIMENTS

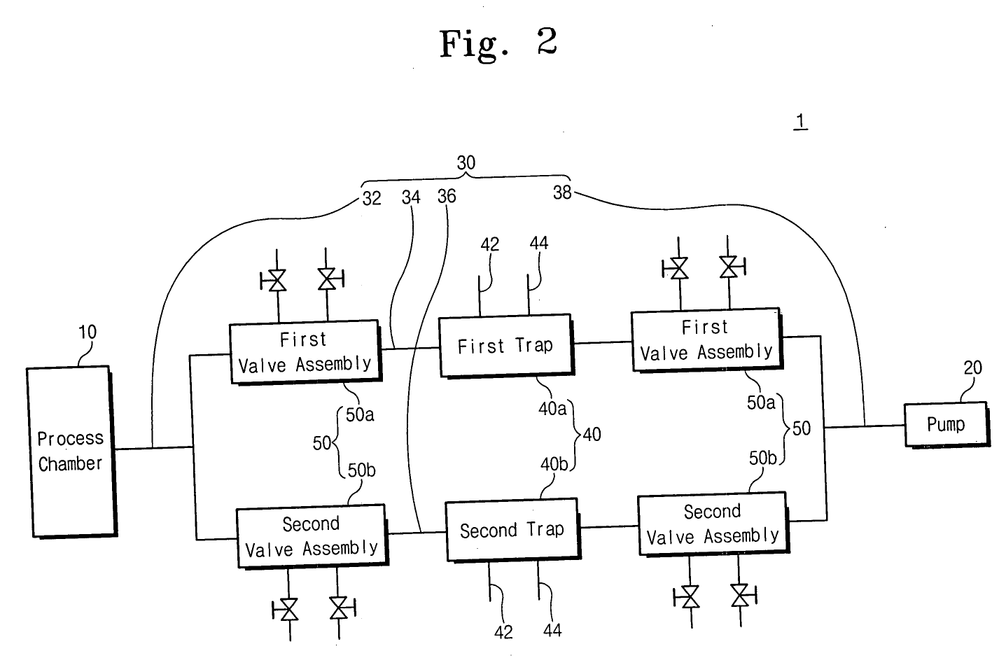

Preferred embodiments of a semiconductor manufacturing apparatus and valve assembly used in the venting system thereof will be described below in more detail with reference to FIGS. 2-7. Like reference numerals designate like elements throughout these figures.

Referring first to FIG. 2, the present invention will be described with reference to a low-pressure chemical vapor deposition (LPVCD) apparatus 1 that forms a film on a wafer under low pressure. However, it is to be understood that the present invention may also be applied to other types of processing apparatuses. In any case, the apparatus 1 includes a process chamber 10 and a venting system. The process chamber 10 may be a single-type of chamber in which a film is formed on one wafer at a time, or the type in which films are simultaneously formed on a plurality of wafers stacked on a boat. The venting system is connected to the process chamber 10 so as to maintain a predetermined pressure in the process chamber 10 during the manufacturing process and exhausts by-products of the manufacturing process (including residue) from the process chamber 10.

The venting system includes a pump 20, a vent line 30 that connects the process chamber 10 to the pump 20, and a system 40 of traps disposed in the vent line 30 to collect by-products which are exhausted from the process chamber 10, and thereby prevent the by-products from flowing into the pump 20.

More specifically, the venting system comprises two traps 40a and 40b so that the processing of wafers in the process chamber 10 can continue uninterrupted when one of the traps 40a and 40b needs to be cleaned. The vent line 30 has a first end section 32 extending from the process chamber 10, a second end section 38 leading to the pump 20, and a first branch 34 and a second branch 36 disposed in parallel as extending between and connected to the first and second sections 32 and 38. Thus, the first end section 32 of the vent line 30 is connected to the second end section 38 by way of the first and second branches 34 and 36. The first trap 40a is installed in the first branch 34, and the second trap 40b is installed in the second branch 36.

The venting system of the semiconductor device manufacturing assembly 1 also includes two valve systems 50 each comprising a first valve assembly 50a and a second valve assembly 50b. The first valve assemblies 50a are installed in the first branch 34 upstream and downstream of the first trap 40a, respectively. Each valve assembly 50a is operable to selectively open and close the the first branch 34. The second valve assemblies 50b are installed in the second branch 36 upstream and downstream of the second trap 40b, respectively. Each second valve assembly is operable to selectively open and close the second branch 36. Preferably, the valve assemblies 50a and 50b all have the same architecture.

Initially, the first valve assemblies 50a are controlled to open the first branch 34 whereas the second valve assemblies 50b are controlled to close the second branch 36. Therefore, by-products exhausted from the process chamber 10 are collected in the first trap 40a. Once a large amount of the by-products have accumulated in the first trap 40a, the first valve assemblies 50a are controlled to close the first branch 34 and the second valve assemblies 50b are controlled to open the second branch 36. Then, the by-products exhausted from the process chamber 10 are collected in the second trap 40b. Also, during this time, the first trap 40a is cleaned or replaced. Then, once a great amount of the by-products have accumulated in the second trap 40b, the second trap 40b is cleaned or replaced while the by-products are trapped in the cleaned or new first trap 40a. In the case in which the trap 40a or 40b is replaced, the trap 40a or 40b is physically separated from the branch 34 or 36. In the case in which the trap 40a or 40b is cleaned, the trap 40a or 40b can be separated from the branch 34 or 36, cleaned, and then reinstalled in the branch 34 or 36. Alternatively, the trap 40a or 40b may be cleaned in situ, i.e., without separating the trap from the branch 34 or 36. In this case, the apparatus 1 includes a cleaner supplying tube 42, a source of cleaning solution connected to the cleaner supply tube and a cleaner discharging tube 44 for supplying a cleaning solution to and discharging the cleaning solution from each trap 40a or 40b. The cleaning solution is preferably de-ionized water.

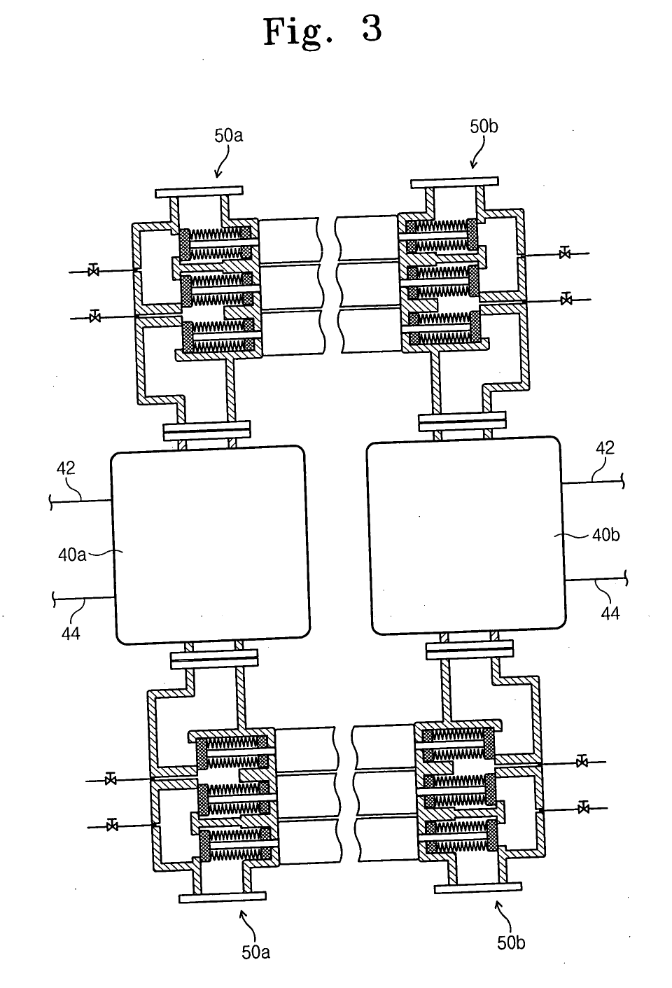

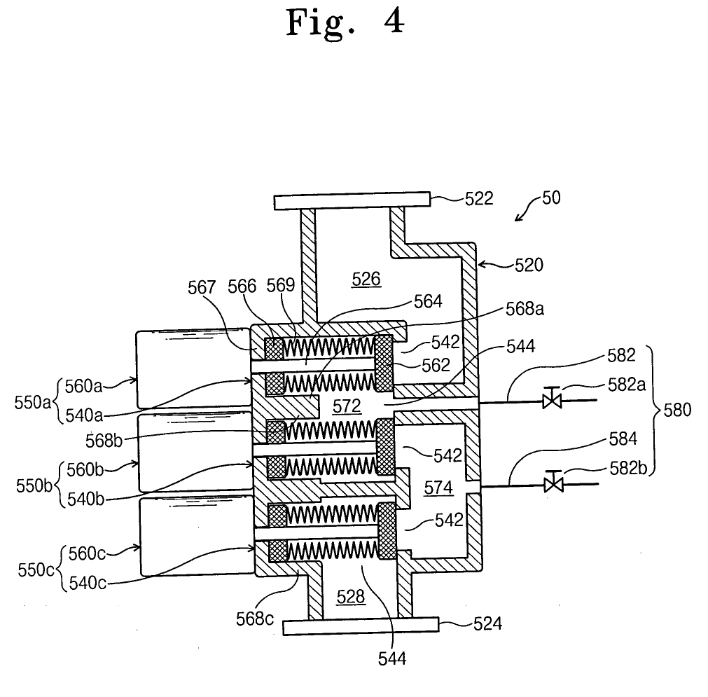

The valve systems 50 of the present invention are configured to completely block the inflow of external pollutants or cleaning solution into the process chamber 10 or the pump 20 while either of the traps 40a and 40b is being cleaned. Referring to FIGS. 3 and 4, each valve assembly 50a or 50b comprises a body 520, a first valve 550a, a second valve 550b, a third valve 550c, and a blocking unit 580. The body 520 has first and second ports 522 and 524 by which the body 520 is connected to a respective branch of the vent line, and defines a passageway through which fluid flows between the first and second ports 522 and 524. The first port 522 is disposed adjacent the trap 40a (or 40b) and may be connected directly thereto. On the other hand, the second port 524 is disposed remotely from the trap 40a (or 40b).

The first valve 550a, the second valve 550b, and the third valve 550c are disposed within the passageway defined by the body 520 in series in the foregoing sequence from the trap 40a (or 40b). The first, second, and third valves, 550a, 550b, and 550c include pneumatic cylinders 560a, 560b, and 560c and first, second, and third housings, 540a, 540b, and 540c, respectively. Each pneumatic cylinder includes a piston rod 564 and a shielding plate 562 fixed to the end of the piston rod 564. The first, second, and third housings 540a, 540b, and 540c are integral parts of the body 520. The body 520 also defines an opening 542 at the front of each of the housings 540a, 540b, and 540c. Also, the first housing 540a has a sidewall 568a confronting the second housing 540b, and an opening 544 is formed in the sidewall 568a. Similarly, the second housing 540b has a sidewall 568b confronting. the first housing 540a, and an opening 544 is formed in the sidewall 568b. The third housing 540c has a sidewall 568c opposite from the second housing 540b, and an opening 544 is formed in the sidewall 568c.

The piston rods 564 of the pneumatic cylinders 560a, 560b, and 560c and the shielding plates 562 fixed thereto extend into the first, second, and third housings 540a, 540b, and 540c, respectively. In addition, plates 566 are each fixed to rear walls 567 of the housings 560a, 560b, and 560c, respectively. Each of the plates 566 has a hole through the center thereof and through which a rod 564 of a respective pneumatic cylinder passes. At its forward position, the shielding plate 562 is seated against a front wall of the housing that defines a front opening 542, thereby closing the front opening 542. In addition, each of the valves 550a, 550b, and 550c may have a bellows 569 surrounding the rod 564 and interposed between the shielding plate 562 and the fixed plate 566.

By the aforementioned structure, the passageway in the body 520 includes a first space 526 located between the first port 522 and the front opening 542 of the first valve 550a, a first region 572 located between adjacent sidewalls of the first and second housings 540a and 540b, a second region 574 located between the front openings 542 of the second and third housings 540b and 540c, and a second space located between the front opening 542 of the third valve 550c and the second port 524. The sidewalls of the first and second housings 540a and 540b, and the sidewalls of the second and third housings 540b and 540c may be discrete or unitary. If the sidewalls of the first and second housings 540a and 540b are unitary, the openings in the sidewalls provide the first region 572. Alternatively, the first region 572 is defined between the front openings of the first and second valves 550a and 550b and the second region 574 is defined by openings formed in adjacent sidewalls of the second and third valves 550b and 550c. In any case, when the first, second, and third valves 550a, 550b, and 550c are open, fluid introduced into the valve assembly 50 through the first port 522 flows to the second port 524 through the first space 526, the first housing 540a, the first region 572, the second housing 540b, the second region 574, and the second space 528.

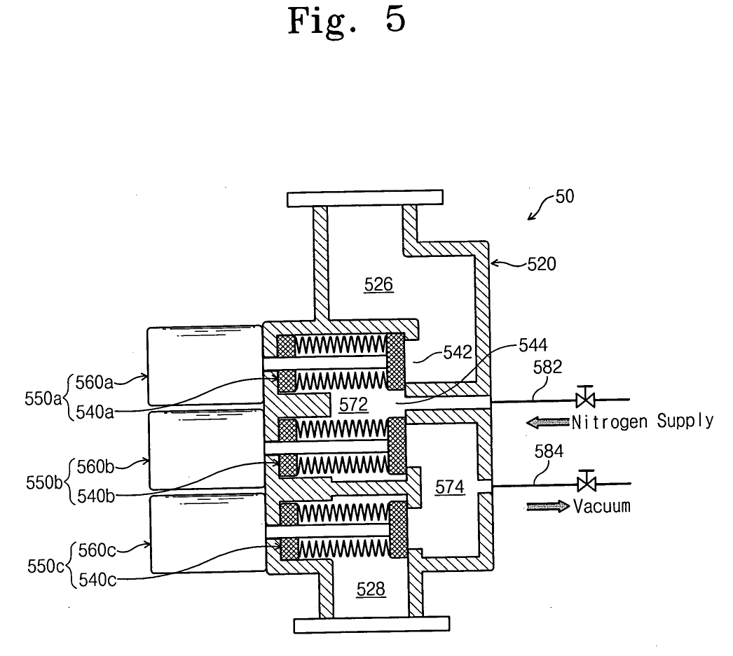

As best shown in FIG. 5, the blocking unit 580 of the valve assembly 50a (or 50b) prevents the pump 20 or the process chamber 10 from being contaminated when the trap 40a (or 40b) is being cleaned. To this end, the blocking unit 580 is associated with the first and second regions 572 and 574. More specifically, the blocking unit 580 comprises a first pressure control unit to adjust pressure in the first region 572, and a second pressure control unit to adjust the pressure in the second region 574. The first pressure control unit includes a gas injection line 582 connected to a source of gas, preferably nitrogen, and the second pressure control unit includes a fluid suction line 584 connected to a vacuum source such as the pump 20. The gas injection line 582 is in direct fluid communication with the first region 572, and gas is injected under high pressure into the first region 572 through the line 582 when the first through third valves 550a -550c are closed. In addition, the blocking unit 580 may include a switching valve 582a disposed in the gas injection line 582 and operable to selectively open and close the line 582 or a flow control valve (not shown) operable to regulate the amount of fluid flowing through the line 582.

In the case in which the trap 40a (or 40b) is separated from the branch 34 (or 36) to be cleaned, a pressure higher than the ambient pressure is preferably maintained in the first region 572. On the other hand, in the case in which the trap 40a (or 40b) is cleaned while remaining connected to the branch 34 (or 36), a pressure higher than that of the cleaning solution supplied to the trap is preferably maintained in the first region 572. Thus, even if a leak existed in the first valve 550a, the high pressure maintained in the first region 572 by the blocking unit 580 would prevent external impurities or the cleaning solution (e.g., de-ionized water) from flowing into the first region 572.

The fluid suction line 584 is provided to prevent impurities or the cleaning solution from flowing into the pump 20 or the process chamber 10 by way of the second region 574. To this end, low pressure, i.e., the suction, is created in the second region 574 through the fluid suction line 584 to draw impurities or the cleaning solution into the second region 574. Preferably, the pressure in the second region 574 is maintained equal to or less than that of the pressure in the first section 32 or the second section 38 of the vent line 30 to prevent fluid from flowing into the pump 20 or the process chamber 10. In addition, a switching valve 582b or a flow control valve (not shown) may be installed in the fluid suction line 584.

FIG. 3 shows that the first region 572 in communication with the gas injection line 582 is located at the side of the valve assembly adjacent the trap 40a (or. 40b) whereas the second region 574 in communication with the fluid suction line 584 is located at the side of the valve assembly remote from the trap 40a (or 40b). However, the present invention is not so limited. Rather, the second region 574 in communication with the fluid suction line 584 may be disposed at the side of the valve assembly adjacent the trap 40a (or 40b) whereas the first region 572 in communication with the gas injection line 582 may be disposed at the side of the valve assembly that is remote from the trap 40a (or 40b).

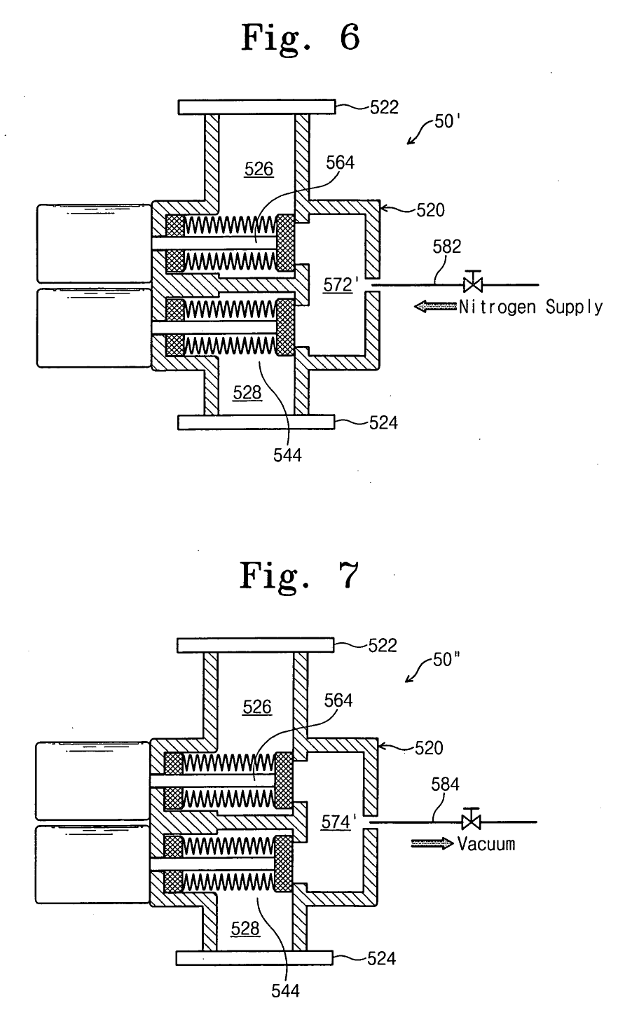

A valve system 50′ comprising another embodiment of a valve assembly according to the present invention is shown in FIG. 6. The valve assembly of this embodiment has a region 572′ in direct fluid communication with a gas injection line 582. FIG. 7 shows a valve system 50″ comprising yet another embodiment of a valve assembly according to the present invention. The valve assembly of this embodiment has a region 574′ in direct fluid communication with a fluid suction line 584.

A method of operating the a semiconductor device manufacturing apparatus or the like according to the invention will now be described with reference to FIGS. 2-5. Although the system shown in FIG. 2 has two first valve assemblies 50a, and two second valve assemblies 50b, for the sake of simplicity reference will be made to only one such first valve assembly 50a and one such second valve assembly 50b.

First, the first valve assembly 50a disposed in the first branch 34 of the vent line 30 is maintained open while the second valve assembly 50b disposed in the second branch 36 of the vent line 30 is maintained closed. Accordingly, by-products of the process carried out in the process chamber 10 are collected in the first trap 40a. After a predetermined period of time, the first valve assembly 50a is closed and the second valve assembly 50b is opened so that by-products of the process carried out in the process chamber 10 are collected in the second trap 40b. The gas injection line 582 and the fluid suction line 584 are maintained closed. Then the first trap 40a is cleaned or replaced. As an example, the case of cleaning the trap 40a will be described.

At this time, the first through third valves 550a -550c of the valve assembly 50a are maintained closed. Nitrogen is supplied into the first region 572 through the gas injection line 582, creating high pressure in the first region 572. And, fluid is drawn out of the second region 574 through the suction line 584, creating negative pressure, i.e., a vacuum, in the second region 574. Then cleaning solution is supplied into the first trap 40a through cleaner supplying tube 42 either once the trap 40a has been detached from the first branch 34 or while it remains attached to the first branch 34. In the case in which the trap 40a is detached from the first branch 34, the trap is reattached to the branch 34 after it has been cleaned. Also, the gas injection line 582 and the fluid suction line 584 are closed.

Then after a predetermined period of time, the first valve assembly 50a is opened and the second valve assembly 50b is closed so that by-products of the process carried out in the process chamber 10 are collected in the first trap 40a. During this time, the second trap 40b may be cleaned in the same way that the first trap 40a was cleaned.

According to the present invention as described above, impurities or a cleaning solution (e.g., de-ionized water) can be prevented from flowing into the process chamber and pump due to leaks in the valves that may occur when the trap is being cleaned.

Although the present invention has been described in connection with the preferred embodiments thereof, the present invention is not so limited. Rather, various substitutions, modifications and changes, as will be apparent to those skilled in the art, may be to the preferred embodiments without departing from the true scope and spirit of the invention as defined by the appended claims.

What is claimed is:

1. A valve assembly for use in a vent line of a semiconductor manufacturing apparatus, comprising:
a body having first and second ports, and defining a passageway therein extending between the first and second ports;
a first valve mounted to the body and openable and closable to selectively open and close the passageway in the body at a side of the body adjacent the first port; and
a second valve mounted to the body and openable and closable to selectively open and close the passageway in the body at a side of the body adjacent the second port, the first and second valves being disposed relative to one another such that a first region of the passageway is located between the first and valves in the body, and wherein the body has an inlet therethrough opening directly into the first region such that pressure in the first region can be controlled to prevent fluid from leaking past the first and second valves when the first and second valves are closed.

2. The valve assembly as set forth in claim 1, further comprising a third valve mounted to the body and openable and closable to selectively open and close the passageway in the body at the side of the body adjacent the second port, wherein the second and third valves are disposed relative to one another such that a second region of the passageway is located between the second and third valves in the body, and the body has an inlet therethrough opening directly into the second region such that pressure in the second region can be controlled to prevent fluid from leaking past the second and third valves when the second and third valves are closed.

3. The valve assembly as set forth in claim 2, wherein the first, second, and third valves are pneumatically operated valves.

4. A substrate processing apparatus comprising:
a process chamber in which substrates are processed;
a vacuum pump;
a vent line extending between and connecting the process chamber and the vacuum pump;
at least one trap disposed in the vent line to collect by-products of the process carried out in the process chamber; and
at least one valve assembly disposed in the vent line, wherein each of the at least one valve assemblies comprises:
a body having first and second ports at which the valve assembly is connected in-line with a said trap, and defining a passageway therein extending between the first and second ports,
a first valve mounted to the body and openable and closable to selectively open and close the passageway in the body at a side of the body adjacent the first port,
a second valve mounted to the body and openable and closable to selectively open and close the passageway in the body at a side of the body adjacent the second port, the first and second valves being disposed relative to one another such that a first region of the passageway is located between the first and valves in the body, and
a pressure control unit in fluid communication with the first region and operative to control the pressure in the first region so that fluid can be prevented from leaking past the first and second valves when the first and second valves are closed.

5. The processing apparatus as set forth in claim 4, wherein the pressure control unit includes a gas injection supply line leading directly into the first region, and a supply of gas to which the gas injection supply line is connected, whereby gas from the supply can be injected into the first region through the gas injection supply line.

6. The processing apparatus as set forth in claim 5, wherein the supply of gas is a source of nitrogen.

7. The processing apparatus as set forth in claim 5, wherein the valve assembly further comprises a third valve mounted to the body and openable and closable to selectively open and close the passageway in the body at the side of the body adjacent the second port, the second and third valves being disposed relative to one another such that a second region of the passageway is located between the second and third valves in the body, and a second pressure unit in fluid communication with the second region such that pressure in the second region can be controlled to prevent fluid from leaking past the second and third valves when the second and third valves are closed.

8. The processing apparatus as set forth in claim 7, wherein the second pressure unit includes a vacuum line leading into the second region, the vacuum line being connected to the vacuum pump.

9. The processing apparatus as set forth in claim 7, wherein the first region is located closer to the trap along the vent line than the second region.

10. The processing apparatus as set forth in claim 7, wherein the first, second, and third valves are pneumatically operated valves.

11. The processing apparatus as set forth in claim 4, and further comprising a cleaning system including a source of a cleaning solution connected to the trap.

12. The processing apparatus as set forth in claim 4, wherein the vent line includes a first section at which the vent line is connected to the process chamber, a second section at which the vent line is connected to the vacuum pump, and first and second branches disposed parallel to one another as extending between and connected to the first and second section, the at least one trap comprises a first trap disposed in the first branch and a second trap disposed in the second branch, and the at least one valve assembly includes first valve assemblies disposed in the first branch at opposite sides of the first trap, respectively, and second valve assemblies disposed in the second branch at opposite sides of second first trap, respectively.

13. The processing apparatus as set forth in claim 7, wherein the vent line includes a first section at which the vent line is connected to the process chamber, a second section at which the vent line is connected to the vacuum pump, and first and second branches disposed parallel to one another as extending between and connected to the first and second section, the at least one trap comprises a first trap disposed in the first branch and a second trap disposed in the second branch, and the at least one valve assembly includes first valve assemblies disposed in the first branch at opposite sides of the first trap, respectively, and second valve assemblies disposed in the second branch at opposite sides of second first trap, respectively.

14. In a substrate processing apparatus having a process chamber in which substrates are processed, a vacuum pump, a vent line extending between and connecting the process chamber and the vacuum pump, a trap disposed in the vent line to collect by-products of the process carried out in the process chamber and a valve assembly disposed in the vent line between the trap and one of the process chamber and the vacuum pump, and wherein the valve assembly comprises a body having first and second ports at which the valve assembly is connected in-line with the trap, the body defining a passageway therein extending between the first and second ports, a first valve mounted to the body and openable and closable to selectively open and close the passageway in the body at a side of the body adjacent the first port, a second valve mounted to the body and openable and closable to selectively open and close the passageway in the body at a side of the body adjacent the second port, the first and second valves being disposed relative to one another such that a first region of the passageway is located between the first and valves in the body, a method of cleaning the trap, the method comprising:
closing the first and second valves to close the passageway extending through the body of the valve assembly;
adjusting the pressure in the first region while the first and second valves are maintained closed to prevent fluid from leaking past the closed valves; and
supplying a cleaning solution into the trap once the pressure in the first region has been adjusted.

15. The method as set forth in claim 14, wherein the adjusting of the pressure in the first region comprises injecting gas into the first region to increase the pressure in the first region.

16. The method as set forth in claim 15, wherein the gas is injected such that the pressure in the first region is raised to above that at which the cleaning solution is under in the trap, and is maintained at least until the supplying of the cleaning solution into the trap is terminated.

17. The method as set forth in claim 15, wherein the gas is nitrogen.

18. The method as set forth in claim 14, wherein the adjusting of the pressure comprises evacuating the first region to reduce the pressure and create suction therein.

19. The method as set forth in claim 14, wherein the first region is evacuated until the pressure therein is less than the pressure prevailing in said one of the process chamber and said vacuum pump.

20. The method as set forth in claim 14, further comprising detaching the trap from the vent line before the cleaning solution is supplied into the trap.

21. The method as set forth in claim 14, wherein the valve assembly also has a third valve mounted to the body and openable and closable to selectively open and close the passageway in the body at the side of the body adjacent the second port, the second and third valves being disposed relative to one another such that a second region of the passageway is located between the second and third valves in the body, further comprising: closing the third valve along with the first and second valves, and adjusting the pressure in the second region while the valves are maintained closed to prevent fluid from leaking past the closed valves, the adjusting of the pressure in the first region comprising injecting gas into the first region to increase the pressure in the first region, and the adjusting of the pressure in the second region comprising evacuating the second region to reduce the pressure and create suction therein.
